(19) United States
(12) Patent Application Publication
(10) Pub. No.: US 2026/0372082 A1
(43) Pub. Date: Nov. 19, 2026

(54) ELECTRONIC DEVICE

(71) Applicant: Innolux Corporation, Miaoli County (TW)

(72) Inventor: Cheng-En Cheng, Miaoli County (TW)

(73) Assignee: Innolux Corporation, Miaoli County (TW)

(21) Appl. No.: 19/647,902

(22) Filed: Apr. 15, 2026

(30) Foreign Application Priority Data
May 13, 2025 (CN) 202510614039.0

(51) Int. Cl. H10W 40/20; H10W 40/22; H10W 70/20; H10W 90/10

(52) U.S. Cl. CPC H10W 40/242; H10W 40/226; H10W 70/20; H10W 90/10

(57) ABSTRACT

An electronic device includes an electronic element, a heat sink, and a conductive structure. The conductive structure is disposed between the electronic element and the heat sink. The conductive structure includes a first metal portion, a second metal portion, and a third metal portion. The first metal portion includes an upper surface, a lower surface, and a side surface. The side surface connects the upper surface and the lower surface, the upper surface faces the heat sink, and the lower surface faces the electronic element. The second metal portion contacts the side surface of the first metal portion. The third metal portion contacts the side surface of the first metal portion. The second metal portion is separated from the third metal portion, and there is a voltage difference between the second metal portion and the third metal portion.

### CROSS-REFERENCE TO RELATED APPLICATION

This application claims the priority benefit of China application serial no. 202510614039.0, filed on May 13, 2025. The entirety of the above-mentioned patent application is hereby incorporated by reference herein and made a part of this specification.

### BACKGROUND

### Technical Field

The disclosure relates to an electronic device that may simultaneously have thermal conduction function and temperature sensing function.

### Related Art

With the vigorous development of electronic devices, electronic devices are developed toward miniaturization and thinning, and thus the reliability or quality requirements for electronic devices are increasingly higher.

### SUMMARY

The disclosure is directed to an electronic device that may simultaneously have thermal conduction function and temperature sensing function.

According to an embodiment of the disclosure, the electronic device includes an electronic element, a heat sink, and a conductive structure. The conductive structure is disposed between the electronic element and the heat sink. The conductive structure includes a first metal portion, a second metal portion, and a third metal portion. The first metal portion includes an upper surface, a lower surface, and a side surface. The side surface connects the upper surface and the lower surface, the upper surface faces the heat sink, and the lower surface faces the electronic element. The second metal portion contacts the side surface of the first metal portion. The third metal portion contacts the side surface of the first metal portion. The second metal portion is separated from the third metal portion, and there is a voltage difference between the second metal portion and the third metal portion.

### BRIEF DESCRIPTION OF THE DRAWINGS

FIG. 1 is a cross-sectional schematic diagram of an electronic device according to First embodiment of the disclosure.

FIG. 2 is a top view schematic diagram of a region R of a conductive structure in the electronic device in FIG. 1.

FIG. 3A is a cross-sectional schematic diagram of the electronic device in FIG. 2 along a cross-sectional line I-I′.

FIG. 3B is a cross-sectional schematic diagram of the electronic device in FIG. 2 along a cross-sectional line II-II′.

FIG. 4 is a top view schematic diagram of a region of the conductive structure in the electronic device according to Second embodiment of the disclosure.

FIG. 5A is a cross-sectional schematic diagram of the electronic device in FIG. 4 along a cross-sectional line III-III′.

FIG. 5B is a cross-sectional schematic diagram of the electronic device in FIG. 4 along a cross-sectional line IV-IV′.

FIG. 6A is a top view schematic diagram of the conductive structure in the electronic device according to Third embodiment of the disclosure.

FIG. 6B is a top view schematic diagram of the conductive structure in the electronic device according to Fourth embodiment of the disclosure.

FIG. 7 is a cross-sectional schematic diagram of the electronic device according to Fifth embodiment of the disclosure.

FIG. 8 is a cross-sectional schematic diagram of the electronic device according to Sixth embodiment of the disclosure.

FIG. 9 to FIG. 10 are cross-sectional schematic diagrams of a manufacturing method of the conductive structure of the electronic device according to Seventh embodiment of the disclosure.

### DESCRIPTION OF THE EMBODIMENTS

The following detailed description and accompanying drawings facilitate an understanding of the disclosure. For clarity, the drawings may illustrate only portions of the device and are not necessarily to scale. Furthermore, element quantities and dimensions are illustrative and do not limit the scope of the disclosure.

Terms such as “comprise” and “on” are open-ended; “on” includes both direct and indirect contact unless “directly” is specified. “First” and “second” are labels that may swap between the specification and claims. “Substantially” implies a range within +10%. Dimensions may be measured via scanning electron microscope (SEM) or other suitable methods. The electronic device applies to displays, automotive devices, assembly units, and sensing devices. It may include active elements (e.g., LEDs, transistors) and peripheral driving systems.

Reference will now be made in detail to exemplary embodiments of the disclosure, examples of which are illustrated in the accompanying drawings. Wherever possible, the same reference numerals are used in the drawings and the description to refer to the same or like parts. For clarity of the drawings and convenience of description, FIG. 2 omits showing several elements in the electronic device (for example, a first insulation layer IL1 and a second insulation layer IL2).

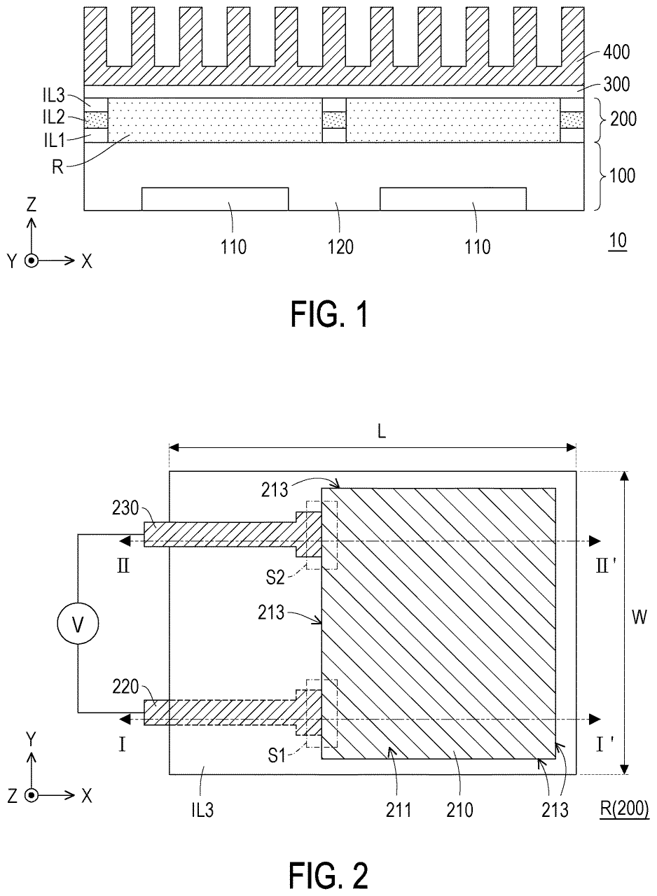

Referring to FIG. 1, an electronic device 10 of the present embodiment may include an electronic element 100, a conductive structure 200, an insulation layer 300, and a heat sink 400.

Specifically, the electronic element 100 includes a plurality of elements 110 (FIG. 1 schematically shows 2 elements 110, but the disclosure is not limited thereto). In the present embodiment, the elements 110 may include chips (for example, known good die (KGD)), diodes, antenna units, sensors, structures of semiconductor-related processes, or structures of semiconductor-related processes disposed on a substrate (for example, polyimide, glass, silicon substrate, or other suitable substrate materials), but the disclosure is not limited thereto. The electronic element 100 further includes an encapsulation material 120. The encapsulation material 120 may prevent the elements 110 from being affected by external moisture, thereby improving the reliability of the electronic device. The material of the encapsulation material 120 includes, for example, epoxy molding compound (EMC), but the disclosure is not limited thereto.

The conductive structure 200 is disposed on the electronic element 100, and the conductive structure 200 is disposed between the electronic element 100 and the heat sink 400. The conductive structure 200 may have a plurality of regions R (FIG. 1 schematically shows 2 regions R, but the disclosure is not limited thereto). Each region R is separated, independent, and does not affect each other, and each region R may simultaneously have thermal conduction function and temperature sensing function. In the present embodiment, the regions R may overlap the elements 110 in a direction Z (for example, the normal direction of the electronic device 10) to conduct heat generated by the elements 110 to the heat sink 400 and simultaneously sense the temperature of the elements 110, but the disclosure is not limited thereto. In the present embodiment, the arrangement of the plurality of regions R may improve the efficiency of thermal conduction and may simultaneously detect temperatures of different regions of the surface of the electronic element 100.

In the present embodiment, a direction X, a direction Y, and the direction Z are respectively different directions. The direction X is, for example, the extending direction of the cross-sectional line I-I′ or the cross-sectional line II-II′, and the direction Z is, for example, the normal direction of the electronic device 10. The direction X is substantially perpendicular to the direction Z, and the direction X and the direction Z are respectively substantially perpendicular to the direction Y, but the disclosure is not limited thereto.

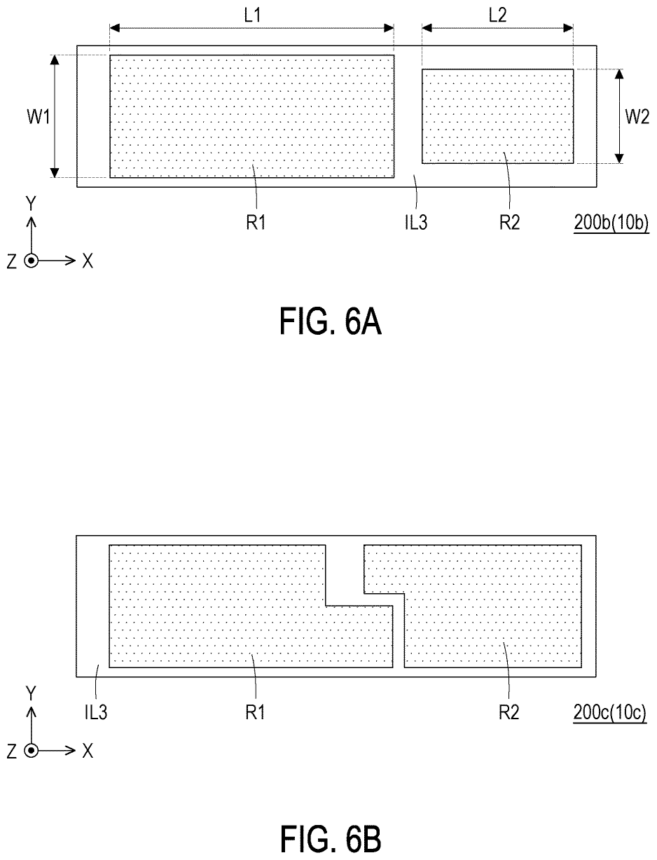

Referring to FIG. 2, in the present embodiment, a length L and a width W of each region R may be substantially the same, and the shape of each region R may be substantially the same, and the shape of each region R may be rectangular, but the disclosure is not limited thereto. In the present embodiment, the length L may be the distance measured along the direction X of the region R, and the width W may be the distance measured along the direction Y of the region R. In some embodiments, the length and/or width of each region R may also be different (as shown in FIG. 6A). In some embodiments, the shape of each region R may also be different (as shown in FIG. 6B). In some embodiments, the shape of each region R may also be any shape other than rectangular (as shown in FIG. 6B). In some embodiments, the size of each region R may be adjusted according to the size of the element 110 that the region overlaps and corresponds to.

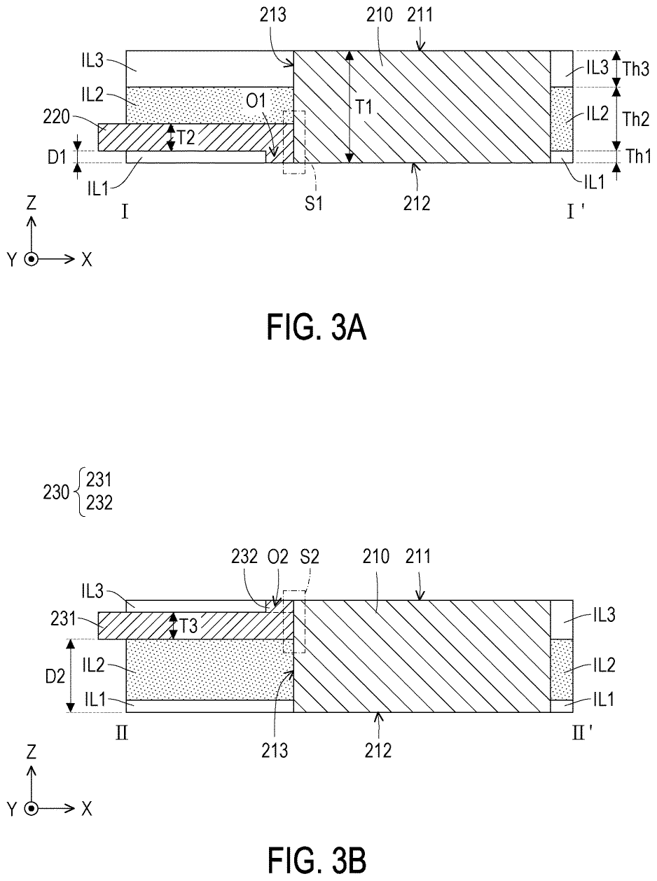

Referring to FIG. 1, FIG. 2, FIG. 3A, and FIG. 3B still, the conductive structure 200 may include a first metal portion 210, a second metal portion 220, a third metal portion 230, a first insulation layer IL1, a second insulation layer IL2, and a third insulation layer IL3.

The following uses one of the regions R as an example to illustrate the arrangement method of the first metal portion 210, the second metal portion 220, the third metal portion 230, the first insulation layer IL1, the second insulation layer IL2, and the third insulation layer IL3, but the disclosure is not limited thereto.

The first metal portion 210 is disposed on the electronic element 100, and the first metal portion 210 at least partially overlaps the electronic element 100. The first metal portion 210 includes an upper surface 211, a lower surface 212, and a side surface 213. The upper surface 211 faces the heat sink 400, the lower surface 212 faces the electronic element 100, and the upper surface 211 and the lower surface 212 are opposite to each other. The side surface 213 connects the upper surface 211 and the lower surface 212. The upper surface 211 and the lower surface 212 of the first metal portion 210 may respectively contact the insulation layer 300 and the electronic element 100 to perform a thermal conduction function (that is, conducting heat generated by the electronic element 100 to the insulation layer 300 through the first metal portion 210). The total area of all side surfaces 213 of the first metal portion 210 (FIG. 2 schematically shows 4 side surfaces 213) is a total area A1. The first metal portion 210 has a thickness T1, and the thickness T1 may be the thickness of the first metal portion 210 measured along the direction Z.

The first insulation layer IL1 is disposed on a portion of the electronic element 100 and surrounds the first metal portion 210. The first insulation layer IL1 has an opening O1. The opening O1 may penetrate through the first insulation layer IL1 to expose the side surface 213 of the first metal portion 210. The first insulation layer IL1 has a thickness Th1, and the thickness Th1 may be the thickness of the first insulation layer IL1 measured along the direction Z.

The second metal portion 220 is disposed on the first insulation layer IL1 and within the opening O1. The second metal portion 220 may contact the side surface 213 of the first metal portion 210. The contact surface between the second metal portion 220 and the first metal portion 210 may serve as a temperature sensing region S1 to perform a temperature sensing function. The contact surface between the second metal portion 220 and the first metal portion 210 has an area A2. In this embodiment, the area A2 may be greater than or equal to 5% of ⅓ of the total area A1 and smaller than or equal to ⅓ of the total area A1, but the disclosure is not limited thereto. The second metal portion 220 has a thickness T2, and the thickness T2 may be the minimum thickness of the second metal portion 220 measured along the direction Z. In this embodiment, the second metal portion 220 and the first metal portion 210 have different materials.

The second insulation layer IL2 is disposed on the second metal portion 220, and the second insulation layer IL2 may cover the first insulation layer IL1 exposed by the second metal portion 220. The second insulation layer IL2 has a thickness Th2, and the thickness Th2 may be the thickness of the second insulation layer IL2 measured along the direction Z.

The third metal portion 230 is disposed on the second insulation layer IL2. The third metal portion 230 does not overlap the second metal portion 220 in the direction Z, but the disclosure is not limited thereto. The third metal portion 230 and the second metal portion 220 are separated from each other. The third metal portion 230 may include a first portion 231 and a second portion 232, and the first portion 231 is disposed between the second insulation layer IL2 and the third insulation layer IL3. The third metal portion 230 may contact the side surface 213 of the first metal portion 210. The contact surface between the third metal portion 230 and the first metal portion 210 may serve as a temperature sensing region S2 to perform a temperature sensing function. The contact surface between the third metal portion 230 and the first metal portion 210 has an area A3. In this embodiment, the area A3 may be greater than or equal to 5% of ⅓ of the total area A1 and smaller than or equal to ⅓ of the total area A1 (that is, 5%×⅓×A1≤A3≤⅓×A1), but the disclosure is not limited thereto. The third metal portion 230 has a thickness T3, and the thickness T3 may be the minimum thickness of the third metal portion 230 measured along the direction Z. In this embodiment, the third metal portion 230 and the first metal portion 210 have different materials, and the third metal portion 230 and the second metal portion 220 have the same material.

The third insulation layer IL3 is disposed on the third metal portion 230, and the third insulation layer IL3 may cover the second insulation layer IL2 exposed by the third metal portion 230. The third insulation layer IL3 has an opening O2. The opening O2 may penetrate through the third insulation layer IL3 to expose the first portion 231 of the third metal portion 230 and the side surface 213 of the first metal portion 210. The second portion 232 of the third metal portion 230 is disposed within the opening O2 of the third insulation layer IL3, and the second portion 232 of the third metal portion 230 may connect to the first portion 231. The third insulation layer IL3 has a thickness Th3, and the thickness Th3 may be the thickness of the third insulation layer IL3 measured along the direction Z.

In this embodiment, the first insulation layer IL1, the second insulation layer IL2, and the third insulation layer IL3 may be single-layer or multi-layer structures, and the first insulation layer IL1, the second insulation layer IL2, and the third insulation layer IL3 may include organic materials (such as polyimide), inorganic materials, or combinations thereof, but the disclosure is not limited thereto.

In this embodiment, the thickness Th1 of the first insulation layer IL1, the thickness Th2 of the second insulation layer IL2, and the thickness Th3 of the third insulation layer IL3 may all be less than or equal to ⅓ of the thickness T1 of the first metal portion 210 (that is, Th1≤⅓×T1, Th2≤⅓×T1, Th3≤⅓×T1), but the disclosure is not limited thereto. In this embodiment, the thickness Th2 of the second insulation layer IL2 may be greater than or equal to the thickness T2 of the second metal portion 220 and the thickness T3 of the third metal portion 230 (that is, T2≤Th2, T3≤Th2), to reduce the risk of short circuit between the second metal portion 220 and the third metal portion 230, but the disclosure is not limited thereto.

In this embodiment, the thickness T1 of the first metal portion 210 may be greater than or equal to 50 micrometers (μm), but the disclosure is not limited thereto.

In this embodiment, the thickness T2 of the second metal portion 220 may be greater than or equal to 10 micrometers and less than or equal to the thickness Th3 of the third insulation layer IL3 (that is, 10 μm≤T2≤Th3), to ensure that the second metal portion 220 has good electrical conduction characteristics, but the disclosure is not limited thereto.

In this embodiment, the thickness T3 of the third metal portion 230 may be greater than or equal to 10 micrometers and less than or equal to the thickness Th3 of the third insulation layer IL3 (that is, 10 μm≤T3≤Th3), to ensure that the third metal portion 230 has good electrical conduction characteristics, but is not limited thereto.

In this embodiment, there is a distance D1 between the second metal portion 220 and the electronic element 100, and the distance D1 may be the minimum distance measured between the second metal portion 220 and the electronic element 100 along the direction Z. There is a distance D2 between the third metal portion 230 and the electronic element 100, and the distance D2 may be the minimum distance measured between the third metal portion 230 and the electronic element 100 along the direction Z. In this embodiment, the distance D1 from the second metal portion 220 to the electronic element 100 may be different from the distance D2 from the third metal portion 230 to the electronic element 100, and the distance D1 from the second metal portion 220 to the electronic element 100 may be less than the distance D2 from the third metal portion 230 to the electronic element 100, but is not limited thereto. In this embodiment, since the second metal portion 220 is closer to the electronic element 100 generating heat than the third metal portion 230, the temperature of a temperature sensing region S1 will be higher than the temperature of a temperature sensing region S2, and there is a temperature difference between the temperature sensing region S1 and the temperature sensing region S2.

In this embodiment, the temperature sensing function of the conductive structure 200 is performed by a thermocouple designed based on the Seebeck effect. In detail, since the material of the first metal portion 210 is different from the materials of the second metal portion 220 and the third metal portion 230, the materials of the second metal portion 220 and the third metal portion 230 are the same, and there is a temperature difference between the temperature sensing region S1 and the temperature sensing region S2, there will be a voltage difference (that is, thermal voltage) between the second metal portion 220 and the third metal portion 230, and the voltage difference may be substantially positively correlated with the temperature difference. That is, when performing the temperature sensing function, when the voltage difference detected is larger, it may indicate that the temperature difference sensed is larger. Furthermore, when the voltage difference detected in one of the multiple regions R of the conductive structure 200 is significantly smaller compared to the voltage differences detected in other regions R, it may indicate that the thermal conduction function of the one region R may have a problem.

Referring to Table 1 below, which exemplifies multiple combinations of materials for the first metal portion 210, the second metal portion 220, and the third metal portion 230 in the conductive structure 200 of this embodiment (that is, a combination 1, a combination 2, a combination 3, and a combination 4), but the disclosure is not limited thereto.

TABLE 1

| | First | Second metal portion/Third |
|---|---|---|
| Combination | metal portion | metal portion |
| 1 | nickel-chromium | aluminum chromium alloy |
| | alloy | |
| 2 | high-purity iron | copper-nickel alloy |
| 3 | nickel-chromium | copper-nickel alloy |
| | alloy | |
| 4 | high-purity copper | copper-nickel alloy |

Referring to FIG. 1, an insulation layer 300 is disposed on the conductive structure 200, and the insulation layer 300 is disposed between the heat sink 400 and the conductive structure 200. The insulation layer 300 has an effect of good thermal conduction and poor electrical conduction. That is, the insulation layer 300 may conduct the heat conducted from the electronic element 100 to the conductive structure 200 to the heat sink 400 to achieve a heat dissipation effect. In this embodiment, the material of the insulation layer 300 may include ceramics (such as aluminum nitride, silicon nitride), diamond, graphite, borosilicate glass, other insulation materials having thermal conduction function, or combinations thereof, but the disclosure is not limited thereto.

Referring to FIG. 1, the heat sink 400 is disposed on the electronic element 100, and the heat sink 400 may be used to dissipate the heat generated by the electronic element 100 to the outside. The material of the heat sink 400 may include copper, graphite, metal, other suitable heat dissipation materials, or combinations thereof, but is not limited thereto.

The electronic device 10 of this embodiment integrates the thermocouple and thermal interface material into the conductive structure 200 through the arrangement and material configuration of the first metal portion 210, the second metal portion 220, and the third metal portion 230, thereby enabling the conductive structure 200 to simultaneously perform temperature sensing function and thermal conduction function, and making the arrangement of the thermocouple in the conductive structure 200 not affect the thermal conduction function and heat dissipation efficiency.

Referring to FIGS. 2, 3A-3B, 4, and 5A-5B, electronic device 10a is similar to device 10, except second and third metal portions 220a, 230a surround first metal portion 210 in the top view.

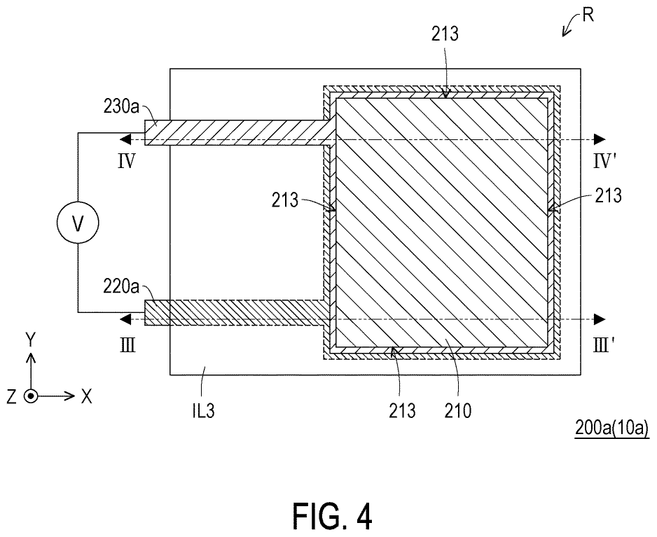

Specifically, referring to FIG. 4, in the top view, the second metal portion 220a may surround and contact the side surface 213 of the first metal portion 210, and the third metal portion 230a may also surround and contact the side surface 213 of the first metal portion 210. In FIG. 4, although the portion of the second metal portion 220a surrounding the first metal portion 210 does not completely overlap with the third metal portion 230, the disclosure is not limited thereto. In other embodiments, the portion of the second metal portion 220a surrounding the first metal portion 210 may completely overlap with the portion of the third metal portion 230a surrounding the first metal portion 210.

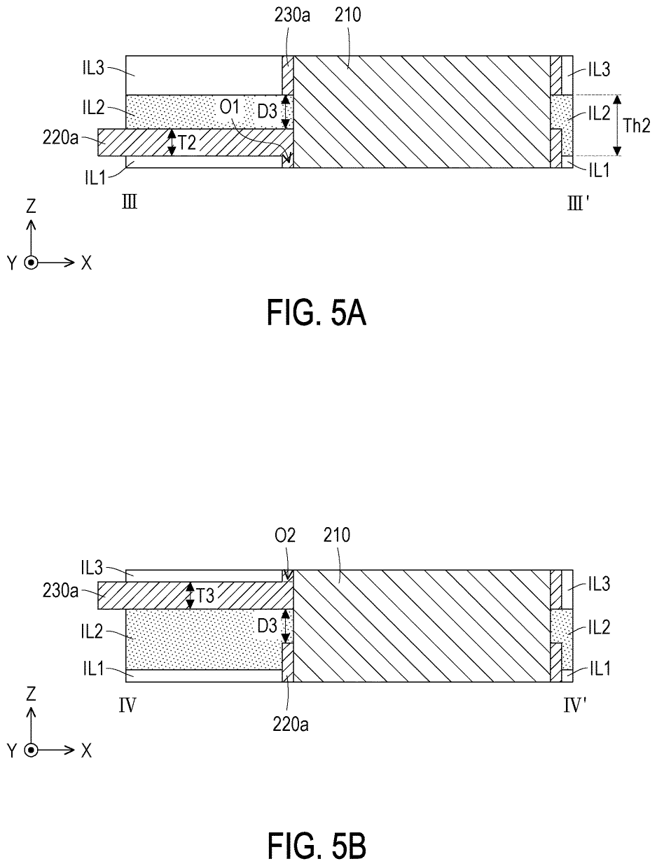

Referring to FIG. 5A and FIG. 5B, which show the case where the portion of the second metal portion 220a and the portion of the third metal portion 230 surround the first metal portion 210 completely overlap, but the disclosure is not limited thereto. The second metal portion 220a and the third metal portion 230a are separated from each other. There is a distance D3 between the second metal portion 220a and the third metal portion 230a, and the distance D3 may be the minimum distance measured between the second metal portion 220a and the third metal portion 230a along the direction Z.

In this embodiment, the distance D3 may be greater than or equal to the thickness T2 of the second metal portion 220 and the thickness T3 of the third metal portion 230 (that is, T2≤D3, T3≤D3), so as to reduce the risk of short circuit between the second metal portion 220 and the third metal portion 230, but the disclosure is not limited thereto.

In this embodiment, the distance D3 may be greater than or equal to 10 micrometers and less than or equal to the thickness Th2 of the second insulation layer IL2 (that is, 10 μm≤D3≤Th2), so as to reduce the risk of short circuit between the second metal portion 220 and the third metal portion 230, but the disclosure is not limited thereto.

Referring to FIGS. 1, 2, and 6A, electronic device 10b is similar to device 10, except regions R1 and R2 of conductive structure 200b have different sizes.

Specifically, referring to FIG. 6A, the region R1 has a length L1 and a width W1, and the region R2 has a length L2 and a width W2. The length L1 and the length L2 may be distances measured along the direction X for the region R1 and the region R2 respectively, and the width W1 and the width W2 may be distances measured along the direction Y for the region R1 and the region R2 respectively. In this embodiment, the length L1 of the region R1 is greater than the length L2 of the region R2, and the width W1 of the region R1 is greater than the width W2 of the region R2. Furthermore, in this embodiment, the shapes of both the region R1 and the region R2 are rectangular.

Referring to FIGS. 1 and 6B, electronic device 10c is similar to device 10, except regions R1 and R2 of conductive structure 200c have different sizes and non-rectangular shapes.

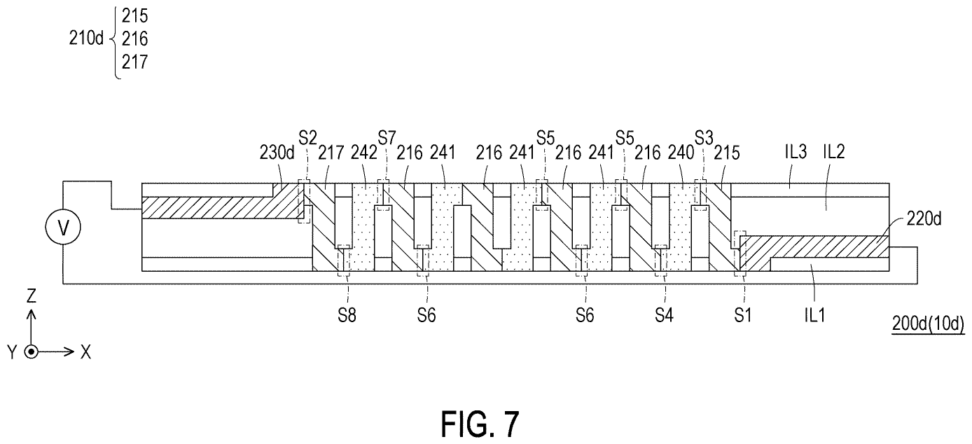

Referring to FIGS. 3A, 3B, and 7, electronic device 10d is similar to device 10, except conductive structure 200d further includes fourth metal portions 240-242, and first metal portion 210d includes segments 215-217.

Specifically, referring to FIG. 7, the first portion 215, the plurality of second portions 216, and the third portion 217 of the first metal portion 210d are separated from each other.

The opposite ends of the first portion 215 may contact the second metal portion 220d and the fourth metal portion 240 respectively. The contact surface between the first portion 215 and the second metal portion 220d may serve as the temperature sensing region S1, and the contact surface between the first portion 215 and the fourth metal portion 240 may serve as a temperature sensing region S3. In this embodiment, the temperature sensing region S1 is closer to the electronic element (not shown) generating heat than the temperature sensing region S3, and thus the temperature of the temperature sensing region S1 is higher than the temperature of the temperature sensing region S3.

The opposite ends of the second portion 216 may contact the fourth metal portion 240 and the fourth metal portion 241 (or the fourth metal portion 242) respectively; or the opposite ends of the second portion 216 may contact different fourth metal portions 241 respectively. The contact surface between the second portion 216 and the fourth metal portion 240 may serve as a temperature sensing region S4. The contact surface between the second portion 216 and the fourth metal portion 241 may serve as a temperature sensing region S5 or temperature sensing region S6. The contact surface between the second portion 216 and the fourth metal portion 242 may serve as a temperature sensing region S7. In this embodiment, both the temperature sensing region S4 and the temperature sensing region S6 are closer to the heat-generating electronic element (not shown) than the temperature sensing region S5 and the temperature sensing region S7, and thus the temperatures of the temperature sensing region S4 and the temperature sensing region S6 are higher than the temperatures of the temperature sensing region S5 and the temperature sensing region S7.

The opposite ends of the third portion 217 may contact the fourth metal portion 242 and the third metal portion 230d respectively. The contact surface between the third portion 217 and the third metal portion 230d may serve as a temperature sensing region S2, and the contact surface between the third portion 217 and the fourth metal portion 242 may serve as a temperature sensing region S8. In this embodiment, the temperature sensing region S8 is closer to the electronic element (not shown) generating heat than the temperature sensing region S2, and thus the temperature of the temperature sensing region S8 is higher than the temperature of the temperature sensing region S2.

The fourth metal portion 240, the fourth metal portion 241, and the fourth metal portion 242 are separated from each other. The fourth metal portions (that is, the fourth metal portion 240, the fourth metal portion 241, and the fourth metal portion 242) have different materials from the first metal portion 210d, and the fourth metal portions (that is, the fourth metal portion 240, the fourth metal portion 241, and the fourth metal portion 242), the third metal portion 230d, and the second metal portion 220d have the same material.

In this embodiment, through the arrangement method and material setting of the first metal portion 210d, the second metal portion 220d, the third metal portion 230d, and the fourth metal portions (that is, the fourth metal portion 240, the fourth metal portion 241, and the fourth metal portion 242), the conductive structure 200d may increase the voltage difference between the second metal portion 220d and the third metal portion 230d through the plurality of temperature sensing regions (that is, the temperature sensing region S1, the temperature sensing region S2, the temperature sensing region S3, the temperature sensing region S4, the temperature sensing region S5, the temperature sensing region S6, the temperature sensing region S7, and the temperature sensing region S8), thereby increasing the sensitivity of the temperature sensing function.

In this embodiment, the first metal portion 210d and the fourth metal portions (that is, the fourth metal portion 240, the fourth metal portion 241, and the fourth metal portion 242) may all be used to perform thermal conduction function to conduct the heat generated by the electronic element (not shown) to the insulation layer and the heat sink.

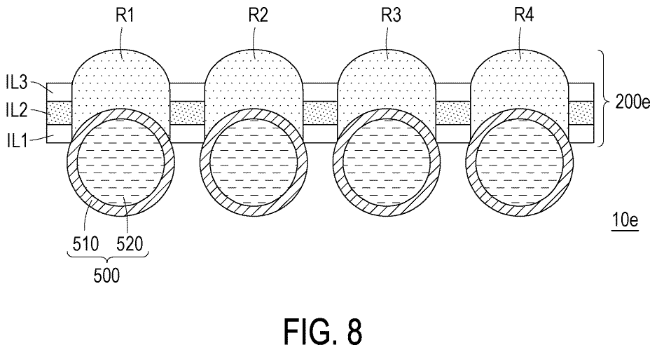

Referring to FIGS. 1 and 8, electronic device 10e is similar to device 10, except liquid cooling pipe 500 replaces electronic element 100.

Specifically, referring to FIG. 8, which shows a portion of the liquid cooling pipe 500 disposed with a region R1, a region R2, a region R3, and a region R4, and the liquid cooling pipe 500 further includes portions (not shown) connected between respective regions. In this embodiment, the liquid cooling pipe 500 includes a cooling pipe 510 and a liquid 520. The cooling pipe 510 has a hollow structure, and the liquid 520 is disposed in the hollow structure of the cooling pipe 510.

The conductive structure 200e is disposed on the liquid cooling pipe 500. The conductive structure 200e has the region R1, the region R2, the region R3, and the region R4 that are separated from each other. The region R1, the region R2, the region R3, and the region R4 may respectively contact a portion of a corresponding one of liquid cooling pipes 500 for re-dispersing the heat conducted from the liquid 520 to the liquid cooling pipe 500 to the surrounding environment or conducting to a heat sink (not shown), and simultaneously for detecting the surface temperature of the liquid cooling pipe 500.

In this embodiment, when the voltage difference detected by one of the regions in the conductive structure 200e (for example, the region R1) is significantly smaller compared to the voltage differences detected by other regions (for example, the region R2, the region R3, and the region R4), it may indicate that there may be liquid leakage at a position adjacent to the liquid cooling pipe 500 corresponding to the one region (for example, the region R1).

Referring to FIGS. 1, 3A-3B, and 9-10, electronic device 10f is similar to device 10, except second metal portion 220f may overlap third metal portion 230f in direction Z. In some other embodiments, the second metal portion 220f of the conductive structure 200f does not overlap the third metal portion 230 in the direction Z, but the conductive structure may still be formed by the manufacturing method described below.

In this embodiment, the manufacturing method of the conductive structure 200f of the electronic device 10f may include the following steps.

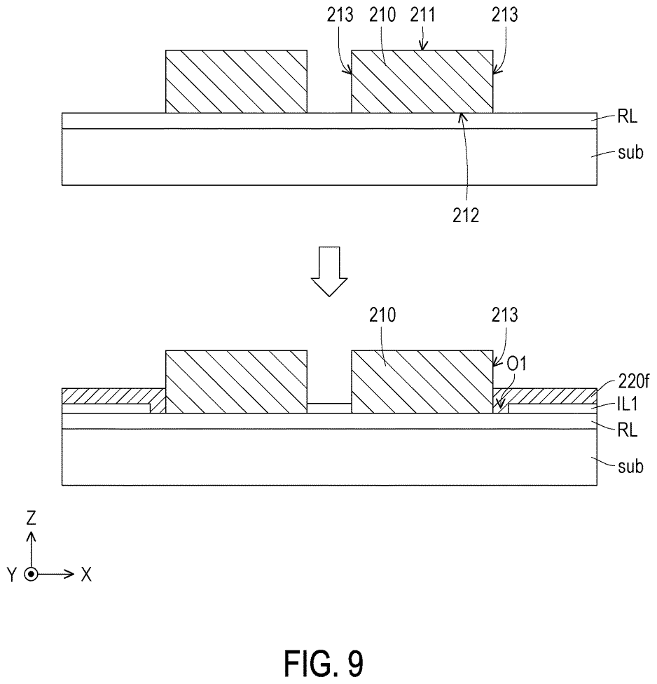

Referring to FIG. 9 first, a substrate sub is provided, a release layer RL is formed on the substrate sub, and a first metal portion 210 is formed on the release layer RL. In detail, for example, the release layer RL is formed by an attaching or coating method; for example, the first metal portion 210 is formed by a method of metal layer deposition combined with photolithography etching, or for example, by a pick up and place method. The first metal portion 210 may expose a portion of the release layer RL. In this embodiment, the material of the substrate sub may include stainless steel, glass, other suitable substrate materials, or combinations thereof, but the disclosure is not limited thereto. In this embodiment, the material of the release layer RL may include thermal release materials that lose the adhesive properties thereof when heated, UV release materials that lose the adhesive properties thereof when exposed to ultraviolet light, other suitable release materials, or combinations thereof, but the disclosure is not limited thereto.

Referring to FIG. 9 still, a first insulation layer IL1 is formed on the portion of the release layer RL exposed by the first metal portion 210. In detail, for example, the first insulation layer IL1 is formed by an attaching or coating method; and an opening O1 is formed in the first insulation layer IL1. The method of forming the opening O1 includes laser drilling, but the disclosure is not limited thereto. The opening O1 may expose a portion of the release layer RL and the side surface 213 of the first metal portion 210. Next, a second metal portion 220f is formed on the first insulation layer IL1 and in the opening O1. For example, the second metal portion 220f is formed by a method combining metal layer deposition and photolithography etching. The second metal portion 220f may contact the side surface 213 of the first metal portion 210, and the second metal portion 220f may expose a portion of the first insulation layer IL1. In some other implementations, a patterned barrier layer may be formed first after forming the opening O1, then metal layer deposition is performed to form the second metal portion 220f, and then the patterned barrier layer is removed to complete the fabrication of the second metal portion 220f. However, the disclosure is not limited to this manufacturing method, and the third metal portion 230f described below may also be manufactured in the same manner, so details will not be repeated here.

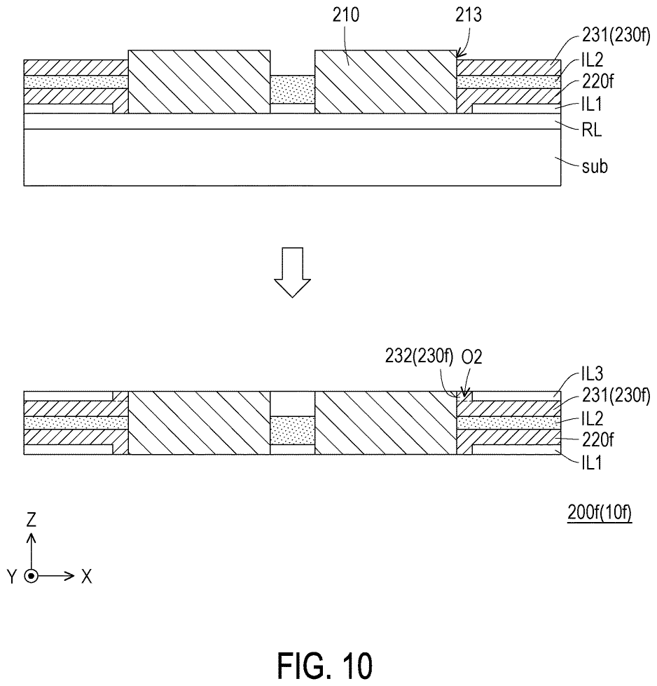

Then, referring to FIG. 10, a second insulation layer IL2 is formed on the second metal portion 220f, and a first portion 231 of a third metal portion 230f is formed on the second insulation layer IL2. In detail, for example, the second insulation layer IL2 is formed by an attaching or coating method; for example, the first portion 231 of the third metal portion 230f is formed by a method of metal layer deposition and photolithography etching. The second insulation layer IL2 may cover the second metal portion 220f and the first insulation layer IL1 exposed by the second metal portion 220f. The first portion 231 of the third metal portion 230f may contact the side surface 213 of the first metal portion 210, and the first portion 231 of the third metal portion 230f may expose a portion of the second insulation layer IL2.

Referring to FIG. 10 still, a third insulation layer IL3 is formed on the third metal portion 230f. In detail, for example, the third insulation layer IL3 is formed by an attaching or coating method; and an opening O2 is formed in the third insulation layer IL3. The method of forming the opening O2 includes laser drilling, but the disclosure is not limited thereto. The opening O2 may expose a portion of the first portion 231 and the side surface 213 of the first metal portion 210. Next, a second portion 232 of the third metal portion 230f is formed in the opening O2 of the third insulation layer IL3. For example, the second portion 232 of the third metal portion 230f is formed by a method of metal layer deposition and photolithography etching. The second portion 232 of the third metal portion 230f may contact the side surface 213 of the first metal portion 210. Next, the substrate sub and the release layer RL are removed.

At this point, the conductive structure 200f of the electronic device 10f of the present embodiment has been substantially completed.

In summary, in the electronic device of an embodiment of the disclosure, through the arrangement and material setting of the first metal portion, the second metal portion, and the third metal portion, the thermocouple and the thermal interface material are integrated into the conductive structure, thereby enabling the conductive structure to simultaneously perform temperature sensing function and thermal conduction function, and making the arrangement of the thermocouple in the conductive structure not affect the thermal conduction function and heat dissipation efficiency.

These embodiments are illustrative, and modifications may be made without departing from the scope of the disclosure.

What is claimed is:

1. An electronic device, comprising:
an electronic element;
a heat sink; and
a conductive structure disposed between the electronic element and the heat sink, and comprising:
a first metal portion comprising an upper surface, a lower surface and a side surface, wherein the side surface connects the upper surface and the lower surface, the upper surface faces the heat sink, and the lower surface faces the electronic element;
a second metal portion contacting the side surface of the first metal portion; and
a third metal portion contacting the side surface of the first metal portion,
wherein the second metal portion and the third metal portion are separated, and there is a voltage difference between the second metal portion and the third metal portion.

2. The electronic device according to claim 1, wherein the second metal portion and the third metal portion have same material.

3. The electronic device according to claim 1, wherein the second metal portion and the first metal portion have different materials, and the third metal portion and the first metal portion have different materials.

4. The electronic device according to claim 1, wherein a distance from the second metal portion to the electronic element is different from a distance from the third metal portion to the electronic element.

5. The electronic device according to claim 1, further comprising:
an insulation layer disposed between the heat sink and the conductive structure.

6. The electronic device according to claim 5, wherein a material of the insulation layer comprises aluminum nitride or silicon nitride.

7. The electronic device according to claim 1, wherein the second metal portion surrounds the first metal portion.

8. The electronic device according to claim 1, wherein the third metal portion surrounds the first metal portion.

9. The electronic device according to claim 1, wherein in one direction, a distance between the second metal portion and the third metal portion is greater than or equal to a thickness of the second metal portion and a thickness of the third metal portion.

10. The electronic device according to claim 9, wherein in the direction, the second metal portion overlaps the third metal portion.
